(19) United States
(12) Patent Application Publication
(10) Pub. No.: US 2021/0043430 A1
(43) Pub. Date: Feb. 11, 2021

(54) SHUTTER FOR OPENING AND CLOSING ENTRANCE OF PROCESS CHAMBER, AND SUBSTRATE PROCESSING APPARATUS INCLUDING THE SAME

(71) Applicant: SEMES Co. Ltd., Cheonan-si (KR)

(72) Inventors: Ju Sun LIM, Pyeongtaek-si (KR); Jeong Seok KANG, Cheonan-si (KR); Sung Yoep KIM, Busan (KR); Inju KIM, Gwangju (KR)

(73) Assignee: SEMES Co. Ltd., Cheonan-si (KR)

(21) Appl. No.: 16/987,489

(22) Filed: Aug. 7, 2020

(30) Foreign Application Priority Data
Aug. 7, 2019 (KR) 10-2019-0096078

(51) Int. Cl. H01J 37/32; H01L 21/67

(52) U.S. Cl. CPC H01J 37/32513; H01L 21/67069; H01J 2237/334; H01J 37/32522; H01J 37/32715

(57) ABSTRACT

The present invention relates to a shutter opening and closing an entrance of a process chamber, and a substrate processing apparatus including the same. The substrate processing apparatus of the present invention includes a process chamber which has a processing space and has an entrance provided at one side thereof to enter and exit a substrate, a substrate support unit which is provided in the processing space to support the substrate, a shutter which is provided in the entrance to open and close the entrance, and a plurality of shutter heaters which are provided in the shutter to transfer heat into the process chamber.

### CROSS-REFERENCE TO RELATED APPLICATION

This application claims the benefit under 35 U.S.C. 119(a) of Korean Patent Application No. 10-2019-0096078 filed on Aug. 7, 2019, in the Korean Intellectual Property Office, the entire disclosure of which is incorporated herein by reference for all purposes.

### TECHNICAL FIELD

The present invention relates to a shutter for opening and closing an entrance of a process chamber, and a substrate processing apparatus including the same and more particularly, to provide a uniform temperature distribution inside the process chamber.

### BACKGROUND ART

In a process of manufacturing a semiconductor device, various processes such as photography, etching, thin film deposition, ion implantation, and cleaning are performed. Among these processes, a substrate processing apparatus using process gas is used for etching, thin film deposition, ion implantation, and cleaning.

In general, a substrate processing apparatus for manufacturing a semiconductor device includes a plurality of process chambers for processing a substrate and a transfer unit. The transfer unit transfers the substrate into the process chamber. The process chamber is provided with a shutter for entering and exiting the substrate.

The shutter is necessary for the entering and exiting of the substrate in the process chamber, but when the shutter is opened, external air may flow in or an ununiform temperature distribution in the process chamber may be caused by a difference in the temperature between the shutter and the periphery of the shutter.

If the temperature distribution in the process chamber becomes ununiform, CDs such as a hole diameter and a line width may become ununiform in the entire area of the substrate in the process chamber. CD ununiformity in an ultra-fine process to be recently introduced may lead to process failure.

### DISCLOSURE

### Technical Problem

The present invention is to solve the problems of the related art described above, and an object of the present invention is to provide a shutter for opening and closing an entrance of a process chamber and a substrate processing apparatus including the same capable of providing a uniform temperature distribution in a process chamber.

### Technical Solution

To achieve the objects descried above, a substrate processing apparatus according to the present invention includes a process chamber which has a processing space and has an entrance provided at one side thereof to enter and exit a substrate; a substrate support unit which is provided in the processing space to support the substrate; a shutter which is provided in the entrance to open and close the entrance; and a plurality of shutter heaters which are provided in the shutter to transfer heat into the process chamber.

Further, in the embodiment, the shutter heaters may be separately controlled.

In the embodiment, the shutter may be driven upward to open the entrance and driven downward to close the entrance, and

In the embodiment, among the plurality of shutter heaters, the lower the shutter heater may be disposed from the shutter, the higher the temperature of the shutter heater may be separately controlled.

In the embodiment, a heat blocking member may be provided on an outer side wall of the shutter to block the heat transfer of the shutter.

In the embodiment, the entrance may include an air curtain formation unit forming an air curtain for preventing inflow of external air and an air curtain recovery unit recovering the air curtain.

In the embodiment, the air curtain formation unit may be provided at one side of left and right sides of the entrance and the air curtain recovery unit may be provided at the other side of the entrance.

In the embodiment, the air curtain may be formed in a horizontal direction.

In the embodiment, the air curtain may be formed when the entrance is opened.

In the embodiment, the substrate processing apparatus may include a side wall chamber heater provided in an inner side wall of the process chamber to transfer heat into the process chamber.

In the embodiment, the substrate processing apparatus may further include an upper wall chamber heater provided in an inner upper wall of the process chamber to transfer heat into the process chamber.

In the embodiment, the substrate processing apparatus may further include a side wall chamber heater provided in an inner side wall of the process chamber to transfer heat into the process chamber and an upper wall chamber heater provided in an inner upper wall of the process chamber to transfer heat into the process chamber.

In the embodiment, a plurality of upper wall chamber heaters and side wall chamber heaters may be provided and separately controlled.

In the embodiment, a temperature of a shutter heater located far from the upper wall chamber heater among the plurality of shutter heaters may be set to be higher than a temperature of a shutter heater located close to the upper wall chamber heater among the plurality of shutter heaters.

In the embodiment, the plurality of shutter heaters may be provided sequentially from the top to the bottom.

In a shutter for opening and closing an entrance of a process chamber according to the present invention, the shutter includes a plurality of shutter heaters to transfer heat into a process chamber.

Further, in the embodiment, the plurality of shutter heaters may be separately controlled.

In the embodiment, the plurality of shutter heaters may be provided in the shutter sequentially from the top to the bottom.

In the embodiment, the shutter may be driven upward to open the entrance and driven downward to close the entrance, and among the plurality of shutter heaters, the lower the shutter heater may be disposed from the shutter, the higher the temperature of the shutter heater may be separately controlled.

### Advantageous Effects

In the substrate processing apparatus according to the present invention, it is possible to provide a uniform temperature distribution in a process chamber by providing an upper wall chamber heater, a side wall chamber heater, and a shutter heater.

According to the present invention, it is possible to minimize the blocking of an air curtain by a substrate when the substrate is entered or existed by forming the air curtain in a horizontal direction which is a right direction at the left of an entrance or a left direction at the right thereof. Therefore, it is possible to effectively prevent air inflow into a processing space in a process chamber when the substrate is entered or existed.

### DESCRIPTION OF DRAWINGS

FIG. 1 is a cross-sectional view showing a substrate processing apparatus according to an embodiment of the present invention.

FIG. 2 is a view for describing a configuration of the substrate processing apparatus that provides a uniform temperature distribution inside a process chamber shown in FIG. 1.

FIG. 3A is a view illustrating the substrate processing apparatus while a shutter is closed, and FIG. 3B is a view illustrating the substrate processing apparatus while the shutter is opened.

### MODES OF THE INVENTION

Embodiments of the present invention can be modified in various forms, and the scope of the present invention should not be interpreted to be limited by embodiments to be described below. The present embodiments will be provided for more completely explaining the present invention to a person with ordinary skill in the art. Therefore, shapes and the like of components in the drawings will be exaggerated to emphasize a clearer description.

In the embodiment, a substrate processing apparatus for etching a substrate using plasma in a chamber will be described as an example. However, the present invention is not limited thereto, and may be applied to all substrate processing apparatuses having a process chamber capable of providing a thermal environment.

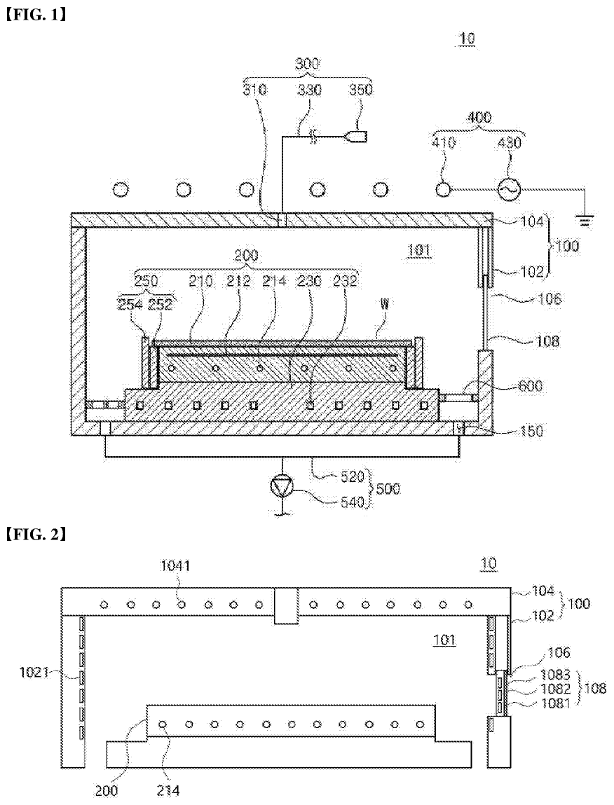

FIG. 1 is a cross-sectional view showing a substrate processing apparatus according to an embodiment of the present invention.

Referring to FIG. 1, a substrate processing apparatus 10 includes a process chamber 100, a substrate support unit 200, a gas supply unit 300, a plasma source 400, an exhaust unit 500, and a baffle unit 600.

The process chamber 100 provides a processing space 101 in which a substrate W is processed. The chamber 100 is provided in a circular cylindrical shape. The processing space is closed by an upper wall and a side wall of the chamber 100. An entrance 106 is formed in a side wall 102 of the chamber 100. The entrance 106 serves as an inlet through which the substrate W is entered and exited. A door 108 is provided on an outer side surface of the chamber 100. The door 108 opens and closes the entrance 106. The chamber 100 is made of a metal material. For example, the chamber 100 may be made of an aluminum material. An exhaust hole 150 is formed on a bottom surface of the chamber 100.

The substrate support unit 200 supports the substrate W in the processing space 101. The substrate support unit 200 may be provided as an electrostatic chuck 200 that supports the substrate W using electrostatic force. Optionally, the substrate support unit 200 may support the substrate W in various methods, such as mechanical clamping.

The electrostatic chuck 200 includes a support plate 210, a focus ring 250, and a base 230. The support plate 210 is provided as a dielectric plate 210 including a dielectric material. The substrate W is directly placed on an upper surface of the dielectric plate 210. The dielectric plate 210 is provided in a disc shape. The dielectric plate 210 may have a smaller radius than that of the substrate W. An internal electrode 212 is provided inside the dielectric plate 210. A power source (not illustrated) is connected to the internal electrode 212 and power is applied from the power source (not illustrated). The internal electrode 212 provides electrostatic force from the applied power (not illustrated) so that the substrate W is adsorbed to the dielectric plate 210. A support unit heater 214 for heating the substrate W is provided inside the dielectric plate 210. The support unit heater 214 may be located below the internal electrode 212.

The support unit heater 214 may be provided as a spiral coil. For example, the dielectric plate 210 may be made of a ceramic material.

The base 230 supports the dielectric plate 210. The base 230 is located below the dielectric plate 210 and fixedly coupled to the dielectric plate 210. An upper surface of the base 230 has a stepped shape such that a central region thereof is higher than an edge region thereof. The base 230 has an area in which the central region of the upper surface thereof corresponds to a lower surface of the dielectric plate 210. A cooling channel 232 is formed inside the base 230. The cooling channel 232 is provided as a passage through which a cooling fluid circulates. The cooling channel 232 may be provided in a spiral shape inside the base 230. The base is connected to a high-frequency power source 234 located outside. The high-frequency power source 234 applies power to the base 230. The power applied to the base 230 guides plasma generated in the chamber 100 to move toward the base 230. The base 230 may be made of a metal material.

The focus ring 250 focuses the plasma on the substrate W. The focus ring 250 includes an inner ring 252 and an outer ring 254. The inner ring 252 is provided in an annular ring shape surrounding the dielectric plate 210. The inner ring 252 is located in an edge region of the base 230. An upper surface of the inner ring 252 is provided to have the same height as the upper surface of the dielectric plate 210. An inner side of the upper surface of the inner ring 252 supports an edge region of the lower surface of the substrate W. For example, the inner ring 252 may be made of a conductive material. The outer ring 254 is provided in an annular ring shape surrounding the inner ring 252. The outer ring 254 is located adjacent to the inner ring 252 in the edge region of the base 230. An upper surface of the outer ring 254 is provided to be higher than the upper surface of the inner ring 252. The outer ring 254 may be made of an insulating material.

The gas supply unit 300 supplies process gas onto the substrate W supported by the substrate support unit 200. The gas supply unit 300 includes a gas storage unit 350, a gas supply line 330, and a gas inlet port 310. The gas supply line 330 connects the gas storage unit 350 and the gas inlet port 310. The process gas stored in the gas storage unit 350 is supplied to the gas inlet port 310 through the gas supply line 330. The gas inlet port 310 is provided on an upper wall of the chamber 100. The gas inlet port 310 is located to face the substrate support unit 200. According to an example, the gas inlet port 310 may be provided at the center of the upper wall of the chamber 100. A valve is provided in the gas supply line 330 to open and close an internal passage thereof, or to regulate a flow rate of gas flowing in the internal passage. For example, the process gas may be etching gas.

The plasma source 400 excites the process gas in the chamber 100 into a plasma state. As the plasma source 400, an inductively coupled plasma (ICP) source may be used. The plasma source 400 includes an antenna 410 and an external power source 430. The antenna 410 is disposed on the outside of the chamber 100. The antenna 410 is provided in a spiral shape wound a plurality of times, and is connected to the external power source 430. The antenna 410 receives power from the external power source 430. The antenna 410 to which power is applied forms a discharge space in the processing space 101 of the chamber 100. The process gas remaining in the discharge space may be excited into the plasma state.

The exhaust unit 500 forms the processing space 101 in a vacuum atmosphere. The exhaust unit 500 includes an exhaust line 520 and a depressurization member 540. The exhaust line 520 is connected to the exhaust hole 150, and the depressurization member 540 is provided in the exhaust line 520.

The depressurization force generated from the depressurization member 540 is transmitted to the processing space 101 through the exhaust line 520. Accordingly, the processing space 101 may be depressurized to form a vacuum atmosphere. The exhaust unit 500 discharges by-products generated during the process and the plasma remaining in the chamber 100 to the outside of the chamber 100 by vacuum pressure.

The baffle unit 600 guides the plasma to be uniformly exhausted from the processing space 101 for each region. The baffle unit 600 is located between the inner side wall of the chamber 100 and the substrate support unit 200 in the processing space 101.

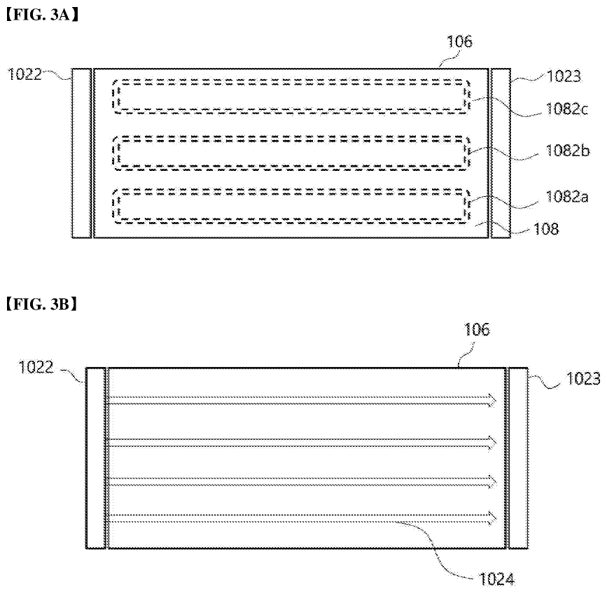

Hereinafter, a configuration of the substrate processing apparatus providing a uniform temperature distribution inside the process chamber will be described in detail with reference to FIGS. 2 to 3B.

FIG. 2 is a view for describing a configuration of the substrate processing apparatus that provides a uniform temperature distribution inside the process chamber shown in FIG. 1.

Referring to FIG. 2, the process chamber 100 includes an upper wall 104 corresponding to an upper surface thereof and a side wall 102 corresponding to a side surface thereof. The process chamber 100 has a processing space 101 closed by the upper wall 104 and the side wall 102.

The upper wall 104 is provided with an upper wall chamber heater 1041 for transferring heat to the processing space 101 in the process chamber 100. In addition, the side wall 102 is provided with a side wall chamber heater 1021 for transferring heat to the processing space 101 in the process chamber 100.

The plurality of upper wall chamber heaters 1041 and side wall chamber heaters 1021 may be provided, and may be separately controlled. The upper wall chamber heater 1041 and the side wall chamber heater 1021 may be provided in various forms, such as a linear shape, a planar shape, a zigzag shape, or a coil shape.

The side wall 102 located on one side among the side walls of the process chamber 100 includes an entrance 106 for entering and exiting the substrate, a side wall chamber heater 1021, an air curtain formation unit 1022, and an air curtain recovery unit 1023.

The entrance 106 serves as a passage for entering and exiting the substrate. The air curtain formation unit 1022 is provided on one side of the left and right sides of the entrance 106 and the air curtain recovery unit 1023 is provided on the other side thereof. The air curtain formation unit 1022 located on one side thereof forms the air curtain 1024 in a horizontal direction toward the air curtain recovery unit 1023 located on the other side thereof. The air curtain formation unit 1022 and the air curtain recovery unit 1023 will be described below with reference to FIG. 3B.

The shutter 108 is provided in the entrance 106, and is driven in a vertical direction by a driver (not illustrated) to open and close the entrance 106. The shutter 108 is inserted into the side wall 102 to open the entrance 106. In addition, the shutter 108 protrudes from the side wall 102 to have a structure of closing the entrance 106. However, the opening and closing structure of the shutter 108 is not limited thereto. The shutter 108 may also be provided at the outside or inside of the side wall 102.

The shutter 108 includes a shutter body 1081, a shutter heater 1082, and a heat blocking member 1083.

The shutter body 1081 forms an outer shape of the shutter 108. The shutter heater 1082 is provided in the shutter body 1081 and transfers heat to the processing space 101 in the process chamber 100. The shutter heater 1082 is provided in the shutter body 1081 to prevent contamination of the shutter heater 1082 during process processing. Unlike this, when the contamination problem of the shutter heater 1082 does not occur during the process processing, the shutter heater 1082 may also be provided to be exposed to the inside instead of the inner portion of the shutter body 1082, that is, the processing space 101.

A plurality of shutter heaters 1082 are provided, and are separately controllable. Therefore, by the plurality of shutter heaters 1082 separately controllable, temperature ununiformity in the process chamber is prevented due to heat loss of the shutters 108.

The upper wall chamber heater 1041 and the side wall chamber heater 1021 may provide a uniform temperature distribution in the process chamber 100 together with the shutter heater 1082. A plurality of upper wall chamber heaters 1041 and side wall chamber heaters 1021 are provided and separately controlled, thereby further uniformizing the temperature inside the process chamber 100.

Accordingly, the substrate may be processed in a thermal environment having a uniform temperature distribution to have a uniform CD distribution over the entire surface of the substrate.

The heat blocking member 1083 is provided outside the shutter heater 1082, and blocks the heat transmitted through the shutter 108. In particular, the heat blocking member 1083 may prevent a temperature change of the shutter 108 by blocking heat loss to the outside.

The substrate support unit 200 is provided in the processing space 101. The substrate support unit 200 includes a heater 214 capable of heating the substrate.

FIG. 3A is a view illustrating the substrate processing apparatus while a shutter is closed, and FIG. 3B is a view illustrating the substrate processing apparatus while the shutter is opened.

FIGS. 3A and 3B, the shutter 108 is driven in a vertical direction to open and close the entrance 106. Specifically, the shutter 108 is driven upward to open the entrance 106, and is driven downward to close the entrance 106.

The substrate processing apparatus while the entrance 106 is closed by the shutter 108 will be described with reference to FIG. 3A.

The shutter 108 is provided with a plurality of shutter heaters 1082a,1082b,and 1082c,and the plurality of shutter heaters may be separately controlled. The first to third shutter heaters 1082a,1082b,and 1082c are sequentially provided from the top to the bottom in the shutter body 1081. The third shutter heater 1082c is provided at a position closest to the upper wall chamber heater 1041, and the first shutter heater 1082a is provided at a position farthest from the upper wall chamber heater 1041. At this time, among the plurality of shutter heaters 1082, the lower the shutter heater is disposed from the shutter 108, the higher the temperature of the shutter heater may be separately controlled.

Specifically, the temperature of the first shutter heater 1082a located far from the upper wall chamber heater 1041 is preferably set to be higher than the temperature of the third shutter heater 1082c located close to the upper wall chamber heater 1041. In the lower portion of the shutter 108 where the first shutter heater 1082a is located, heat loss due to external air may exist. Accordingly, during the process processing, the first shutter heater 1082a may be set to a higher temperature than the third shutter heater 1082c. The upper portion of the shutter 108 where the third shutter heater 1082c is located has little heat loss due to external air and is located close to the upper wall chamber heater 1041. Accordingly, during the process processing, the third shutter heater 1082c may be set to a lower temperature than the first shutter heater 1082a. The second shutter heater 1082b located between the first shutter heater 1082a and the third shutter heater 1082c may be set to an intermediate temperature therebetween.

The substrate processing apparatus while the entrance 106 is opened will be described with reference to FIG. 3B.

Referring to FIG. 3B, when the shutter 108 is opened and the entrance 106 is opened, the air curtain formation unit 1022 located on one side thereof forms an air curtain 1024 in the horizontal direction toward the air curtain recovery unit 1023 located on the other side thereof. The air curtain recovery unit 1023 recovers the air curtain 1024.

When the air curtain is formed in the vertical direction from the top to the bottom of the entrance, the air curtain formed in the vertical direction when entering and exiting a substrate having a circular plate shape may be blocked by the substrate. When the air curtain is blocked, the air may flow in from either the upper portion or the lower portion of the substrate. The inflow of the air may change the temperature in the process chamber 100.

According to the present invention, it is possible to minimize the blocking of the air curtain by the substrate when the substrate is entered or existed by forming the air curtain 1024 in a horizontal direction which is a right direction at the left of the entrance 106 or a left direction at the right thereof. Therefore, it is possible to effectively prevent the air inflow into the processing space 101 in the process chamber 100 when the substrate is entered or existed.

In the substrate processing apparatus according to the present invention, it is possible to provide a uniform temperature distribution of the processing space in the process chamber by providing the upper wall chamber heater, the side wall chamber heater, and the shutter heater.

### EXPLANATION OF REFERENCE NUMERALS AND SYMBOLS

| | |
|---|---|
| 10: Substrate processing apparatus | 100: Process chamber |
| 102: Side wall | 1021: Side wall chamber heater |
| 1022: Air curtain formation unit | 1023: Air curtain recovery unit |
| 1024: Air curtain | 104: Upper wall |
| 1041: Upper wall chamber heater | 106: Entrance |
| 108: Shutter | 1081: Shutter body |
| 1082: Shutter heater | 1083: Heat blocking member |

1. A substrate processing apparatus comprising:
a process chamber which has a processing space and has an entrance provided at one side thereof to enter and exit a substrate;
a substrate support unit which is provided in the processing space to support the substrate;
a shutter which is provided in the entrance to open and close the entrance; and
a plurality of shutter heaters which are provided in the shutter to transfer heat into the process chamber.

2. The substrate processing apparatus of claim 1, wherein the shutter heaters are separately controlled.

3. The substrate processing apparatus of claim 2, wherein the shutter is driven upward to open the entrance and driven downward to close the entrance, and
among the plurality of shutter heaters, the lower the shutter heater is disposed from the shutter, the higher the temperature of the shutter heater is separately controlled.

4. The substrate processing apparatus of claim 1, wherein a heat blocking member is provided on an outer side wall of the shutter to block the heat transfer of the shutter.

5. The substrate processing apparatus of claim 1, wherein the entrance includes an air curtain formation unit forming an air curtain for preventing inflow of external air and an air curtain recovery unit recovering the air curtain.

6. The substrate processing apparatus of claim 5, wherein the air curtain formation unit is provided at one side of left and right sides of the entrance and the air curtain recovery unit is provided at the other side of the entrance.

7. The substrate processing apparatus of claim 5, wherein the air curtain is formed in a horizontal direction.

8. The substrate processing apparatus of claim 5, wherein the air curtain is formed when the entrance is opened.

9. The substrate processing apparatus of claim 1, comprising:
a side wall chamber heater provided in an inner side wall of the process chamber to transfer heat into the process chamber.

10. The substrate processing apparatus of claim 1, further comprising:
an upper wall chamber heater provided in an inner upper wall of the process chamber to transfer heat into the process chamber.

11. The substrate processing apparatus of claim 1, further comprising:
a side wall chamber heater provided in an inner side wall of the process chamber to transfer heat into the process chamber and an upper wall chamber heater provided in an inner upper wall of the process chamber to transfer heat into the process chamber.

12. The substrate processing apparatus of claim 11, wherein a plurality of upper wall chamber heaters and side wall chamber heaters are provided and separately controlled.

13. The substrate processing apparatus of claim 11, wherein a temperature of a shutter heater located far from the upper wall chamber heater among the plurality of shutter heaters is set to be higher than a temperature of a shutter heater located close to the upper wall chamber heater among the plurality of shutter heaters.

14. The substrate processing apparatus of claim 1, wherein the plurality of shutter heaters are provided sequentially from the top to the bottom.

15. A shutter for opening and closing an entrance of a process chamber providing a thermal environment, wherein the shutter includes a plurality of shutter heaters to transfer heat into a process chamber.

16. The shutter of claim 15, wherein the plurality of shutter heaters are separately controlled.

17. The shutter of claim 16, wherein the plurality of shutter heaters are provided in the shutter sequentially from the top to the bottom.

18. The shutter of claim 17, wherein the shutter is driven upward to open the entrance and driven downward to close the entrance, and
among the plurality of shutter heaters, the lower the shutter heater is disposed from the shutter, the higher the temperature of the shutter heater is separately controlled.
